(19) United States
(12) Patent Application Publication
(10) Pub. No.: US 2007/0038905 A1
(43) Pub. Date: Feb. 15, 2007

(54) Information storage medium, information recording/playback apparatus, and method of recording and playing back information

(76) Inventors: Toru Uno, Yokohama-Shi (JP); Toshihiko Kaneshige, Yokohama-Shi (JP); Naoto Mihara, Yokohama-Shi (JP); Hiroaki Morino, Yokohama-Shi (JP); Yukiyasu Tatsuzawa, Yokohama-Shi (JP); Minako Morio, Kawasaki-Shi (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/493,976

(22) Filed: Jul. 27, 2006

(30) Foreign Application Priority Data
Jul. 28, 2005 (JP) 2005-219612

(51) Int. Cl. G11C 29/00

(52) U.S. Cl. 714/710

(57) ABSTRACT

A rewritable information storage medium includes a user area for storing user data, a spare area serving as a replacement area for storing user data that was unable to be stored in the defective area, and a plurality of defect management areas. The same defect management information is stored in the plurality of defect management areas. Even when all errors of the plurality of defect management areas are uncorrectable on a predetermined data unit basis, in the case where the error of the defect management information stored in any one of the defect management areas is correctable on a data unit basis smaller than the predetermined data unit, the defect management information is compensated for on the basis of the smaller data unit.

### PRIORITY INFORMATION

This application is based on and claims priority to Japanese Patent Application No. 2005-219612, filed on Jul. 28, 2005, the entire contents of which is incorporated herein by reference.

### BACKGROUND OF THE INVENTION

1. Field of the Invention

The present invention relates to an information storage medium, an information recording/playback apparatus, and a method of recording and playing back information, in particular, to a rewritable information storage medium including an optical disk, an information recording/playback apparatus for recording information onto and playing back information from the information storage medium, and a method of recording and playing back the information.

2. Description of the Related Art

Known information storage media which can have information rewritably recorded thereon (e.g., optical disks) include a mechanism to compensate for a “defective recording area” thereon. An area used for managing the defect recording area is referred to as a “defect management area (DMA)”.

As the number of defective recording areas increases, the DMA is overwritten. In general, the characteristics of the information recording medium deteriorate due to overwriting. Accordingly, the maximum number of allowed overwrites is restricted. If a medium has a relatively small maximum number of allowed overwrites (such as a high-density optical disk using a blue laser), overwriting for updating the DMA becomes problematic. That is, as the number of overwritings increases, the DMA itself, which records the defect information, may become defective.

Accordingly, JP 2004-288285 A, for example, describes a technology in which the defect management information is stored in a plurality of physically separated areas so that redundancy is added to the defect management information. Thus, even when one DMA becomes defective, the defect management information stored in another DMA can compensate for the defective defect management information. Furthermore, technology has been proposed in which, when the number of DMA updates exceeds a predetermined maximum number of allowed overwrites, the defect management information stored in that DMA is relocated to another DMA.

The information storage medium described in JP 2004-288285 A (e.g., an optical disk) includes a spare area in addition to a user area that generally stores ordinary data (user data). If part of the user area becomes defective, the user data to be stored in that defective part of the user area is relocated to the spare area. The replacement of the user data area is made on a predetermined data unit basis (This data unit is referred to as an “ECC block”).

When user data in a replacement area is played back (is read out), defect management information that associates address information about the defective original area with address information about the replacement area is required. The DMA stores such defect management information. The DMA is provided in an area different from the user area and the spare area.

Known DVD-RAMs and the next generation high-density optical disks (such as HD DVD-RWs) include four DMAs: two DMAs in the innermost peripheral area and two DMAs in the outermost peripheral area of the optical disks. The same defect management information is stored in these four DMAs. Consequently, even when a dust is deposited onto one of the DMAs or one of the DMAs is damaged, the defect management information in the other DMAs is normal. Thus, the reliability of the defect management information can be increased.

Additionally, for the HD DVD-RWs, which have a smaller maximum number of allowed overwrites than the DVD-RAMs, each of the four DMAs is separated into a plurality of sub-DMAs (e.g., 100 sub-DMAs). When the number of overwrites to the DMA is about to exceed the maximum number of allowed overwrites or the error rate of data exceeds a predetermined range, the defect management information in that DMA is relocated to another DMA. By sequentially repeating this operation, up to 100 updates can be allowed.

Furthermore, like normal user data, the defect management information stored in the DMA is encoded using an error correction code. Consequently, within a predetermined number of errors, the defect management information can be corrected on an ECC block basis by using the error correction code.

Thus, a variety of techniques have been proposed in order to increase the reliability of the defect management information stored in the DMA. However, the possibility of read errors occurring in all the defect management information still exists.

If the number of errors exceeding the number of correctable errors occurs in the defect management information stored in the DMA, the errors become uncorrectable on an ECC block basis. Therefore, the defect management information is lost. If all the defect management information stored in the DMAs are uncorrectable and unreadable, the stored user data cannot be played back. Therefore, a user suffers a great loss.

Therefore, means for recovering the defect management information stored in the DMA is strongly expected even when the number of errors exceeding the number of correctable errors occurs in the defect management information stored in the DMA on an ECC block basis.

### SUMMARY OF THE INVENTION

Accordingly, it is an object of the present invention to provide an information storage medium, an information recording/playback apparatus, and a method of recording and playing back information that are capable of correctly reading defect management information stored in the DMA even when the number of errors exceeding the maximum number of correctable errors occurs in the defect management information stored in the DMA on an ECC block basis and that are capable of preventing the loss of user data.

According to an embodiment of the present invention, a rewritable information storage medium includes a user area for storing user data, a spare area serving as a replacement area for storing user data that was unable to be stored in the defective area, and a plurality of defect management areas, each storing the same defect management information, the defect management information being used for playing back the user data relocated and stored in the replacement area, the defect management information being encoded on a predetermined data unit basis using a predetermined error correction code. Even when all errors of the plurality of defect management areas are uncorrectable on the predetermined data unit basis, in the case where the error of the defect management information stored in any one of the defect management areas is correctable or the error is not found on a data unit basis smaller than the predetermined data unit, the defect management information is compensated for on the basis of the smaller data unit.

According to another embodiment of the present invention, an information recording/playback apparatus for recording data on and playing back data from a rewritable information storage medium includes first storing means for storing user data in a user area, second storing means for storing user data that was unable to be stored in a defective area of the user area in a spare area serving as a replacement area, third storing means for encoding defect management information on a predetermined data unit basis using a predetermined error correction code and storing the same defect management information in a plurality of defect management areas, the defect management information being used for playing back the user data relocated and stored in the replacement area, and compensating means for compensating for the defect management information on a data unit basis smaller than the predetermined data unit in the case where the error of the defect management information stored in any one of the defect management areas is correctable or the error is not found on the basis of the smaller data unit even when all errors of the plurality of defect management areas are uncorrectable on the predetermined data unit basis.

According to still another embodiment of the present invention, an information recording/playback method for recording data on and playing back data from a rewritable information storage medium includes the steps of storing user data in a user area, storing user data that was unable to be stored in a defective area of the user area in a spare area serving as a replacement area, encoding defect management information on a predetermined data unit basis using a predetermined error correction code and storing the same defect management information in a plurality of defect management areas, the defect management information being used for playing back the user data relocated and stored in the replacement area, and compensating for the defect management information on a data unit basis smaller than the predetermined data unit in the case where the error of the defect management information stored in any one of the defect management areas is correctable or the error is not found on the basis of the smaller data unit even when all errors of the plurality of defect management areas are uncorrectable on the predetermined data unit basis.

According to the present invention, an information storage medium, an information recording/playback apparatus, and a method of recording and playing back information are provided that are capable of correctly reading defect management information stored in the DMA even when the number of errors exceeding the maximum number of correctable errors occurs in the defect management information stored in the DMA on an ECC block basis and that are capable of preventing the loss of user data.

### BRIEF DESCRIPTION OF THE DRAWINGS

FIG. 1 is a schematic illustration of the physical data layout of a rewritable information storage medium (e.g., a next-generation DVD, an HD DVD-RW, and an HD DVD-RAM);

FIG. 2 is a schematic illustration of the data structure of the information storage medium;

FIG. 3 illustrates the data structure of a DMA 1 and a DMA 2 recorded in a lead-in area and a DMA 3 and a DMA 4 recorded in a lead-out area;

FIG. 4A illustrates an exemplary data structure of a DDS/PDL;

FIG. 4B illustrates an exemplary data structure of an SDL;

FIG. 5 illustrates an exemplary byte allocation of the DDS and expected values of a known DVD;

FIG. 6 illustrates an exemplary byte allocation of the DDS and expected values of an HD DVD-RW;

FIG. 7 illustrates an exemplary byte allocation of the PDL and expected values of the known DVD and the HD DVD-RW;

FIG. 8 illustrates an exemplary byte allocation of the SDL and expected values of the known DVD and the HD DVD-RW;

FIG. 9 illustrates the data structure of a known DVD when user data, the DDS/PDL, and the SDL are recorded in the DVD;

FIG. 10 illustrates the error correction in a known DVD when the user data, DDS/PDL, and SDL are read out;

FIG. 11 illustrates the data structure of an ECC block of the next-generation DVD (such as HD DVD-RW);

FIG. 12 illustrates the structure of a sector of the HD DVD-RW;

FIG. 13 is a diagram illustrating an exemplary system configuration of an information recording/playback apparatus according to an embodiment of the present invention;

FIG. 14 is a flow chart of a compensating operation on defect management information;

FIG. 15 is a flow chart of a detailed reserved data compensating operation;

FIG. 16 is a flow chart of an operation for detecting the reserved area;

FIGS. 17A and 17B illustrate flow charts of the comparing operation between PI rows in the different DMAs;

FIGS. 18A and 18B illustrate flow charts of the comparing operation between sectors in the different DMAs;

FIG. 19 is a schematic diagram for illustrating a PI row compensating operation and a sector compensating operation;

FIGS. 20A and 20B illustrate flow charts of the PI row compensating operation;

FIGS. 21A and 21B illustrate flow charts of the sector compensating operation;

FIG. 22 illustrates an example of the details of PDL update history information and the recording location of the PDL update history information;

FIG. 23 is a flow chart of an exemplary procedure for generating the PDL update history information; and

FIGS. 24A and 24B illustrate a PDL compensating operation using the PDL update history information.

### DETAILED DESCRIPTION OF THE PREFERRED EMBODIMENT

An information storage medium, an information recording/playback apparatus, and a method of recording and playing back information according to an embodiment of the present invention are now herein described with reference to the accompanying drawings.

(1) Data Structure of Information Storage Medium

An information storage medium 1 according to an embodiment of the present invention and the data structure of the information storage medium 1 on which an information recording/playback apparatus 100 records information and from which an information recording/playback apparatus 100 plays back information are described next.

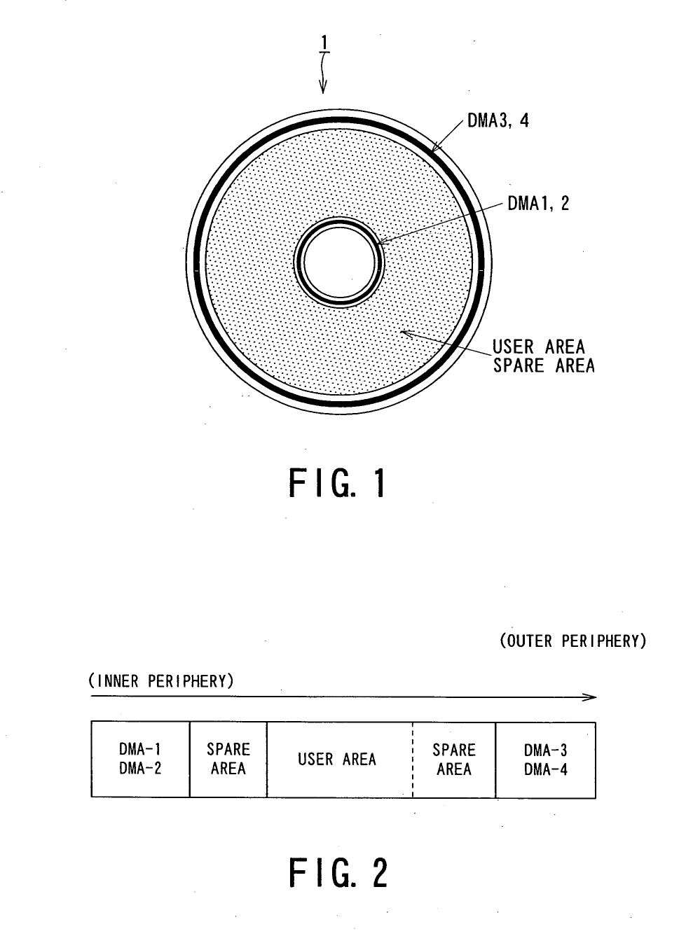

FIG. 1A is a schematic illustration of a physical data layout of the rewritable information storage medium 1 (e.g., a next-generation DVD: an HD DVD-RW or an HD DVD-RAM).

The recording surface of the information storage medium 1 is mostly occupied by a user area. Part of the user area is used as a spare area. The user area stores user data, such as video and audio data and data of a variety of information. If data is not correctly written to the user area, the spare area is used as a replacement area for the area (defective area) into which the data has not been correctly written. The data to be stored in the defective area is written into the spare area.

A ring-shaped region called a “data lead-out area” is provided in an outer periphery of the user area, which includes the spare area. The data lead-out area includes a sub-area called a “defect management area (DMA)”.

Additionally, a ring-shaped region called a “data lead-in area” is provided in an inner periphery of the user area. The data lead-in area also includes a DMA.

FIG. 2 schematically illustrates the data structure of the information storage medium 1. As described above, the information storage medium 1 includes the data lead-in area in the inner periphery thereof and the data lead-out area in the outer periphery thereof. In the data lead-in area, a DMA 1 and a DMA 2 are provided at physically close locations. Similarly, in the data lead-out area, a DMA 3 and a DMA 4 are provided at physically close locations. However, the DMAs 1 and 2 are located at positions physically distant from those of the DMAs 3 and 4.

Spare areas are provided in the inner periphery and the outer periphery of the user area. If part of the user area becomes defective, user data to be written to the defective area is relocated to and stored in the spare areas.

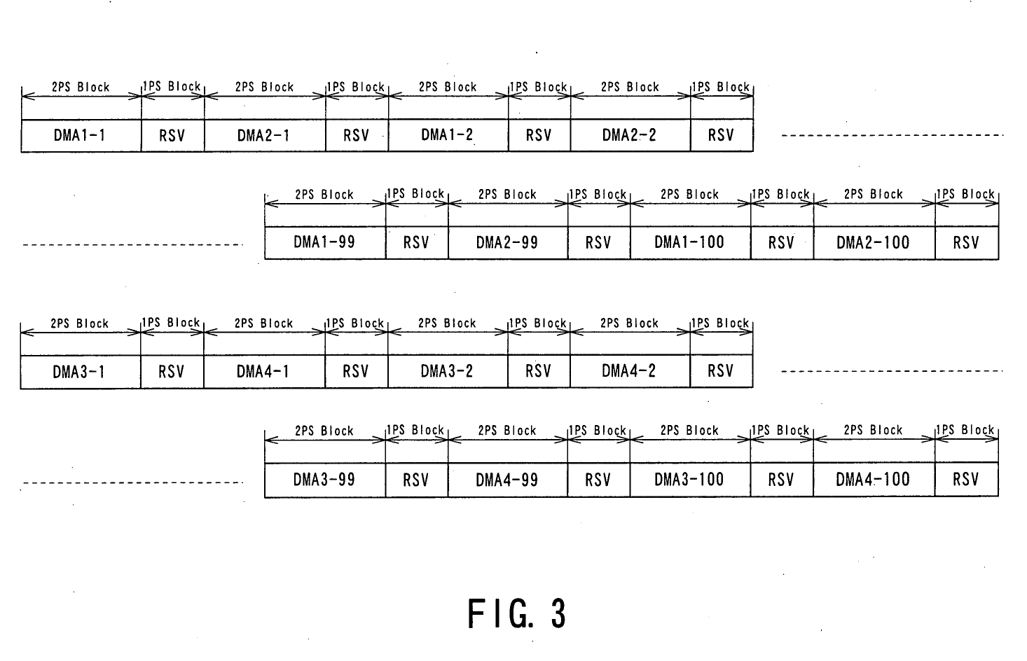

FIG. 3 illustrates the data structure of the DMA 1 and DMA 2 recorded in the lead-in area and the DMA 3 and DMA 4 recorded in the lead-out area.

For an HD DVD-RW, which is a next-generation DVD, the DMA 1 and the DMA 2 recorded in the lead-in area have 100 units of the DMA (i.e., DMAs 1-1 to 1-100) and 100 units of the DMA (i.e., DMAs 2-1 to 2-100), respectively. That is, each of the DMAs 1 and 2 is a set of 100 units of the DMA.

Similarly, the DMA 3 and the DMA 4 recorded in the lead-out area have 100 units of the DMA (i.e., DMAs 3-1 to 3-100) and 100 units of the DMA (i.e., DMAs 4-1 to 4-100), respectively. That is, each of the DMAs 3 and 4 is a set of 100 units of the DMA.

In addition, each of the lead-in area and the lead-out area includes 100 reserved blocks “RSV”.

The defect management information stored in the DMA includes information for associating the address (old address) of the unwritable area (defective area) with an address (new address) of a spare area used for an alternative data writing area. Even when user data is not recorded in the data area due to some defect of the data area, the user data can be reliably played back by referencing the defect management information in the DMA and reading out the address information about the expanded user area, the defect information, and the user data recorded in the alternative spare area during playback.

The same defect management information is recorded in the DMAs 1 to 4. By recording the same defect management information in the four physically separated areas, even when one of the DMAs becomes unreadable due to a defect, such as a scratch or fingerprint on the disk, the defect management information can be read from one of the other DMAs. Thus, fault tolerance can be increased.

If a new defect is found in the data area, information about the defect is written to the DMAs. Thus, the defect management information in the DMAs is updated (overwritten) every time a defect is found. The rewritable information storage medium 1 gradually deteriorates with the overwriting. That is, the DMA itself deteriorates. Accordingly, for example, the HD DVD-RWs include a plurality of changeable DMAs (more specifically, 100 DMA subsets). If the number of overwritings to one DMA exceeds a predetermined number or if a possibility of unreadable data being created increases (i.e., the symbol error rate exceeds a predetermined value), the defect management information is copied to the next DMA and the currently used DMA is changed to the next DMA. By sequentially repeating this operation, the change can be made up to 100 times.

It is noted that, in known DVDs (such as DVD-RAMs), the DMA is not relocated. The lead-in area includes one DMA 1 and one DMA 2. The lead-out area includes one DMA 3 and one DMA 4.

Each subset of the DMA includes defect management information called a DDS/PDL and defect management information called an SDL.

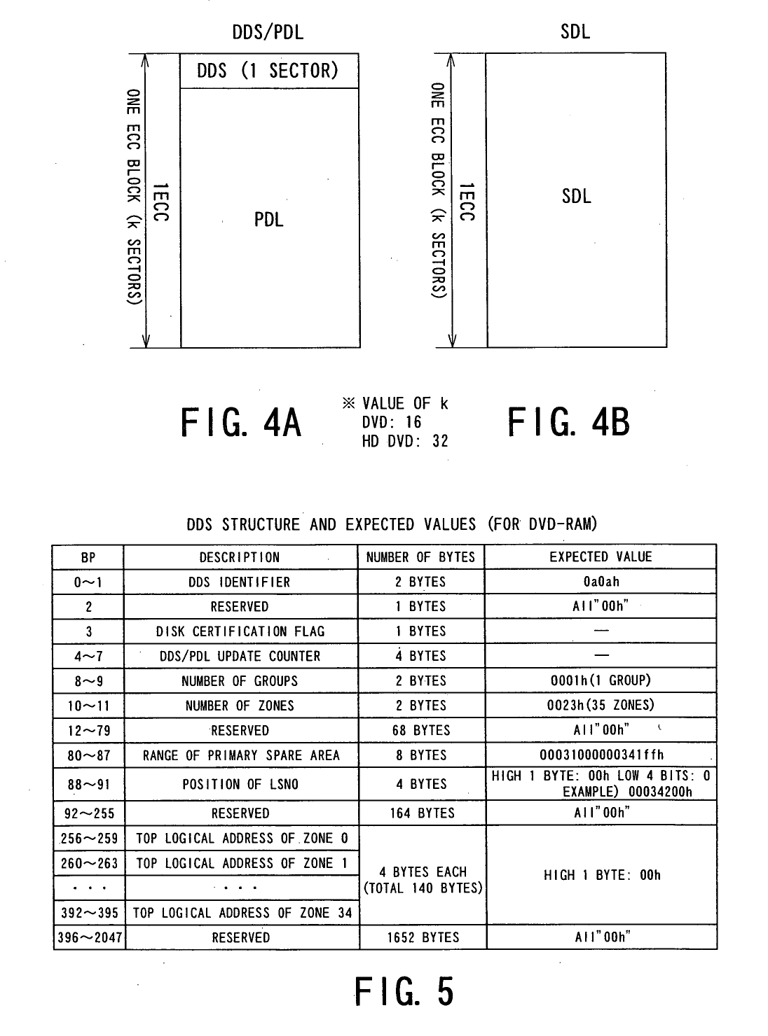

FIG. 4A illustrates an exemplary data structure of the DDS/PDL, while FIG. 4B illustrates an exemplary data structure of the SDL.

Each of the DDS/PDL and SDL of the DMA is composed of data blocks called ECC blocks. A predetermined error correction code (ECC) is allocated to each ECC block. Within a predetermined number of errors, a symbol error can be corrected on an ECC block basis.

The ECC block is divided into units of data called sectors. Depending on the type of the information storage medium 1, the information storage medium 1 has an ECC block including 16 sectors or 32 sectors. For example, for known DVDs, one ECC block includes 16 sectors. In contrast, for next-generation DVDs (e.g., HD DVD-RWs), one ECC block includes 32 sectors. The ECC block including 32 sectors is also referred to as a “PS block (Physical Segment Block)”.

The data size of a sector is 2 Kbytes regardless of the type of the information storage medium 1. Therefore, for known DVDs, the data size of the ECC block is 32 Kbytes (16 sectors×2 Kbytes). For HD DVD-RWs, the data size of the ECC block is 64 Kbytes (32 sectors×2 Kbytes).

The DDS/PDL block is divided into a region called a DDS (disc definition structure) and a region called a PDL (primary defect list). The data size of the DDS is 2 Kbytes (one sector).

FIG. 5 illustrates an exemplary byte allocation and expected values of the DDS. In the DDS, information about the definition and structure of the disk (e.g., the “DDS identifier”, the “number of groups”, and the “number of zones”) and information about the physical address of the write start position (“LSN0”) are recorded.

The DDS data includes a portion that varies in accordance with the operating time of the disk and a portion representing a value that is constant regardless of the operating time of the disk. The entries of the expected values in FIG. 5 show the values that are constant regardless of the operating time of the disk as “expected values” for the corresponding data.

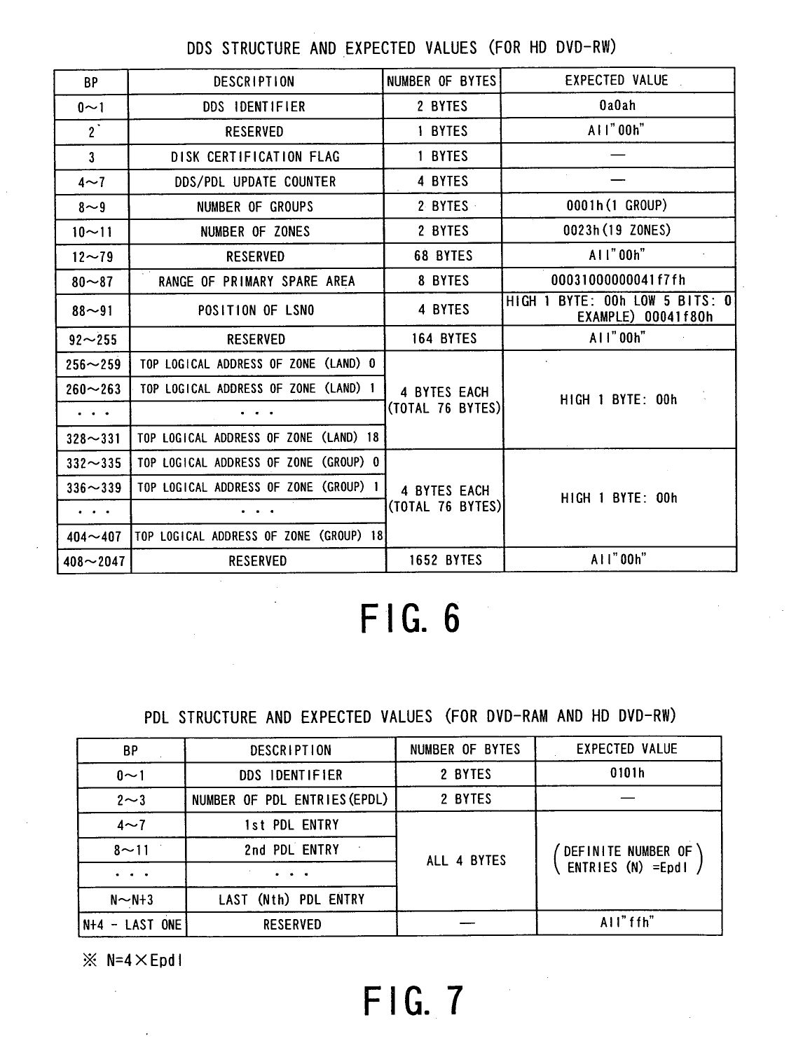

Similarly, FIG. 6 illustrates the byte allocation and the expected values of the DDS in an HD DVD-RW.

The PDL is a primary defect list for storing information about initial defects. The data size of the PDL is the size determined by subtracting the data size of the DDS from the size of the DDS/PDL block (ECC block). For the known DVDs, the size of the PDL is 30 Kbytes (15 sectors×2 Kbytes). For HD DVD-RWs, the size of the PDL is 62 Kbytes (31 sectors×2 Kbytes).

In the PDL, defect management information about, for example, defects made at time of manufacturing, defects found at a certification time of the first formatting, and defects moved from the SDL at a formatting time after the disk has started to be used are recorded.

FIG. 7 illustrates an exemplary byte allocation and expected values of the PDL for the known DVDs and the HD DVD-RWs. Like the DDS, the PDL data includes a portion that varies in accordance with the operating time of the disk and a portion representing a value that is constant regardless of the operating time of the disk. The entries of the expected values in FIG. 7 show the values that are constant regardless of the operating time of the disk as “expected values” for the corresponding data.

The PDL contains the following fields from the head to the tail thereof: a 2-byte identifier (“PDL identifier”); a 2-byte field for storing the number of PDL entries in the DDS/PDL block (“Number of entries in the PDL”); and a zone for sequentially storing PDL entries, each being 4 bytes.

Each PDL entry includes information for managing one initial defect. The number of the PDL entries depends on the number of initial defects. As the number of initial defects increases, the number of the PDL entries increases. When the number of PDL entries indicates that the end of the DDS/PDL block is not reached, a “reserved area” remains. The entire reserved area is filled with bits of “1”. That is, all the byte values of the expected value are “ff” (hexadecimal).

The PDL stores defective management information relating to a primary defect (initial defect), whereas the SDL stores defective management information relating to a secondary defect. That is, the SDL stores defective management information relating to a defect found at a recording time of normal user data (the secondary defect).

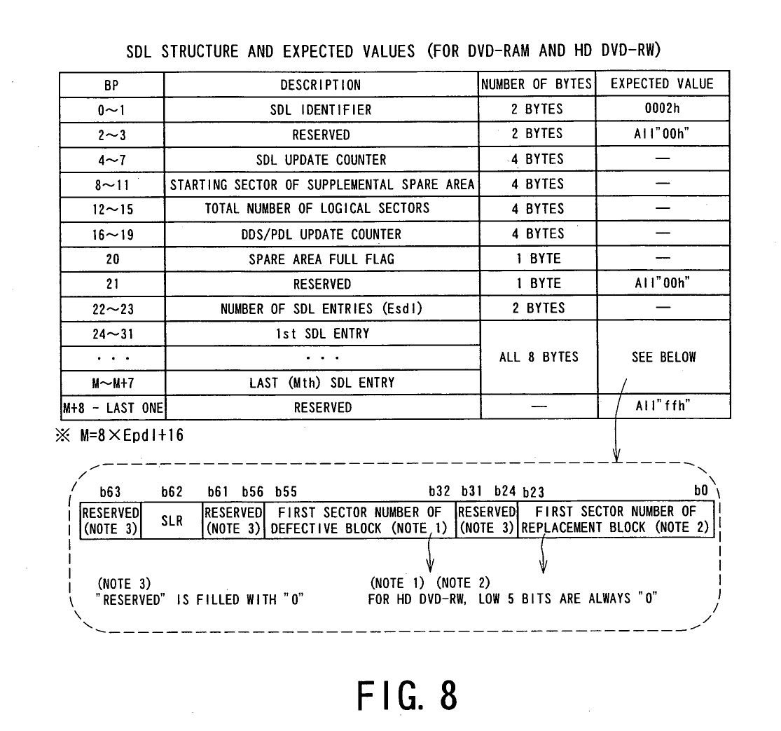

FIG. 8 illustrates an exemplary byte allocation and expected values of the SDL for the known DVDs and the HD DVD-RWs.

The SDL contains the following fields from the head to the tail thereof: information fields used for managing the SDL itself, such as an identifier; a 2-byte field starting from byte 22 for storing the number of SDL entries in the SDL block; and a zone for sequentially storing SDL entries, each being 8 bytes.

Each SDL entry includes information for managing one secondary defect. The number of SDL entries depends on the number of secondary defects. As the number of secondary defects increases in accordance with the use of the information storage medium 1, the number of SDL entries increases.

When the number of SDL entries indicates that the end of the SDL block is not reached, a “reserved area” remains. The entire reserved area is filled with bits of “1”. That is, all the byte values of the expected value are “ff” (hexadecimal).

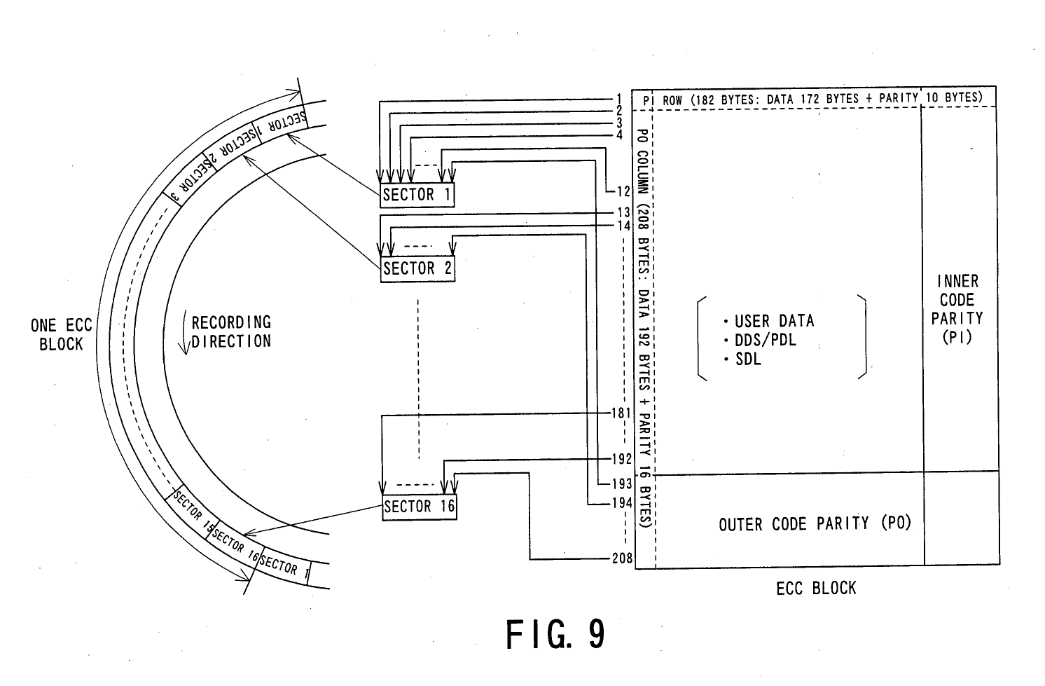

FIG. 9 illustrates the data structure of a known DVD when user data, the DDS/PDL, and the SDL are recorded in the DVD.

In the known DVD, each of the user data, the DDS/PDL, and the SDL is recorded on an ECC block basis. As shown in FIG. 9, the ECC block is divided into 16 sectors (sectors 1 to 16).

As shown in the right side of FIG. 9, each sector includes data of 13 rows: data of 12 rows and an outer parity code (a PO code) of 1 row. Each row contains 182-byte data: 172-byte data and a 10-byte inner parity code (a PI code).

The PI code enables error correction in the row direction. In the row direction, theoretically, errors of up to 10 symbols can be corrected. Additionally, the PO code enables error correction in the column direction. In the column direction, theoretically, errors of up to 16 symbols can be corrected.

The data structure (array) of the ECC block including these parity codes has a column of (172+10) bytes (i.e., 182-byte column) in the transverse direction and (12 rows×16+16) rows (i.e., 208 rows) in the longitudinal direction. Since the PI code is used for the error correction in the row direction, the row is also referred to as a “PI row”. Similarly, since the PO code is used for the error correction in the column direction, the column is also referred to as a “PO column”.

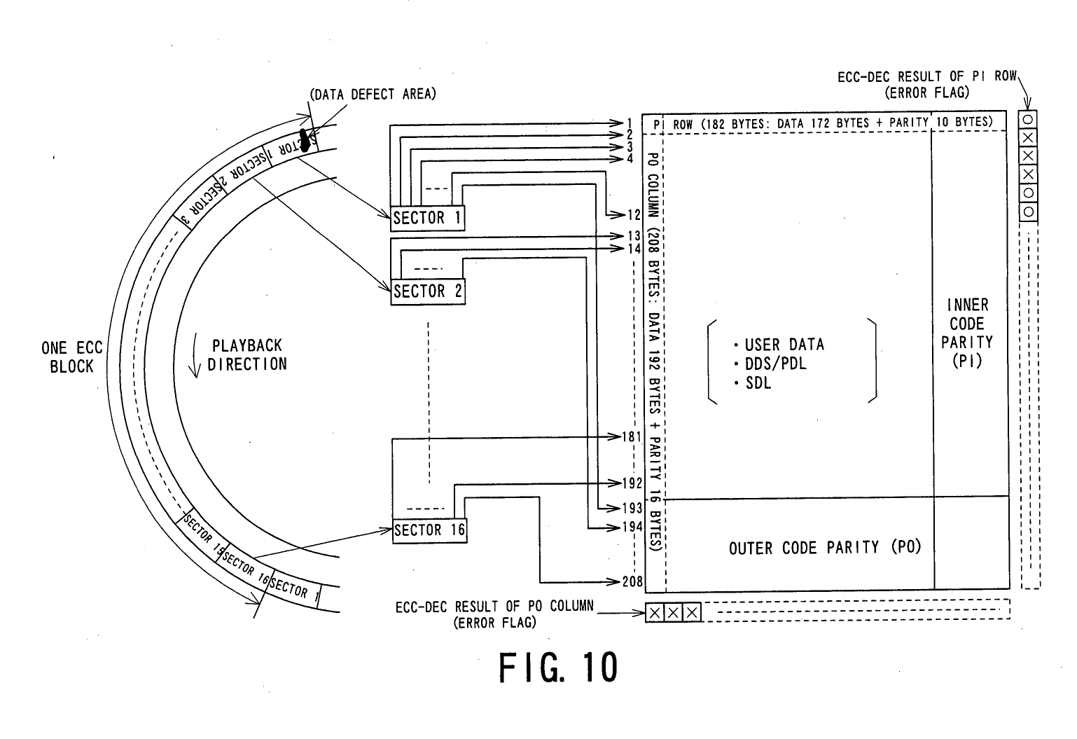

FIG. 10 illustrates the error correction in a known DVD when the user data, DDS/PDL, and SDL are read out. In the column represented by symbols “O” and “X” in the rightmost area of FIG. 10, the symbol “O” indicates successful correction of the PI row using the PI code whereas the symbol “X” indicates unsuccessful correction of the PI row using the PI code.

Similarly, in the row represented by symbols “O” and “X” in the bottom area of FIG. 10, the symbol “O” indicates successful correction of the PO column using the PO code while the symbol “X” indicates unsuccessful correction of the PO column using the PO code.

The error correction using the PI code and the PO code allows errors in the PI row and the PO column to be independently corrected. Accordingly, even when an error in the PI row cannot be corrected due to a burst of errors being present in a particular row, the error in the PI row can be corrected by using the PO code in the case where the number of errors in the PO column is small.

For example, as shown by an example in FIG. 10, when a burst of data losses occur in a sector 1, a burst of data losses occur in the PI row corresponding to the sector 1 (i.e., in the first PI row to the twelfth PI row). However, few errors occur in the other PI rows. In such a case, by carrying out error correction in the longitudinal direction using the PO code, the errors in the first PI row to the twelfth PI row may be corrected. Thus, the error correction using the PI code and the PO code is excellent for the burst errors.

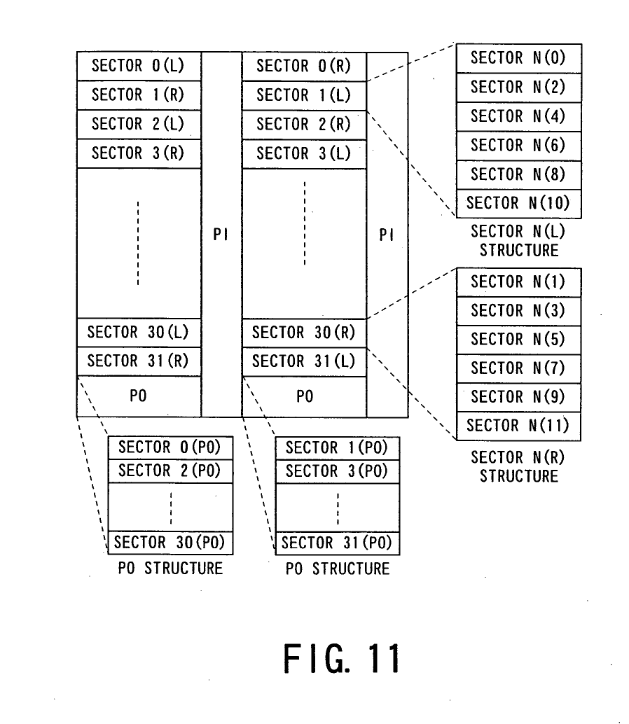

FIG. 11 illustrates the data structure of the ECC block of a next-generation DVD (such as an HD DVD-RW). As noted above, the ECC block of the HD DVD-RW includes 32 sectors: a sector (0) to a sector (31). Additionally, each sector is separated into a sector N (L) and a sector N (R) (N=0 . . . 31). Each of the sectors N (L) and sector N (R) includes 6 PI rows. One sector includes 12 PI rows. The data size of the sector is the same as that of the known DVD. The data size of each row is 172 bytes, which is also the same as that of the known DVD.

The parity code for correcting an error includes a 10-byte PI code attached to each row having 172 bytes and a 16-row PO code attached to the set of 192 rows in the longitudinal direction (6 rows×32). This design is the same as that of the known DVD.

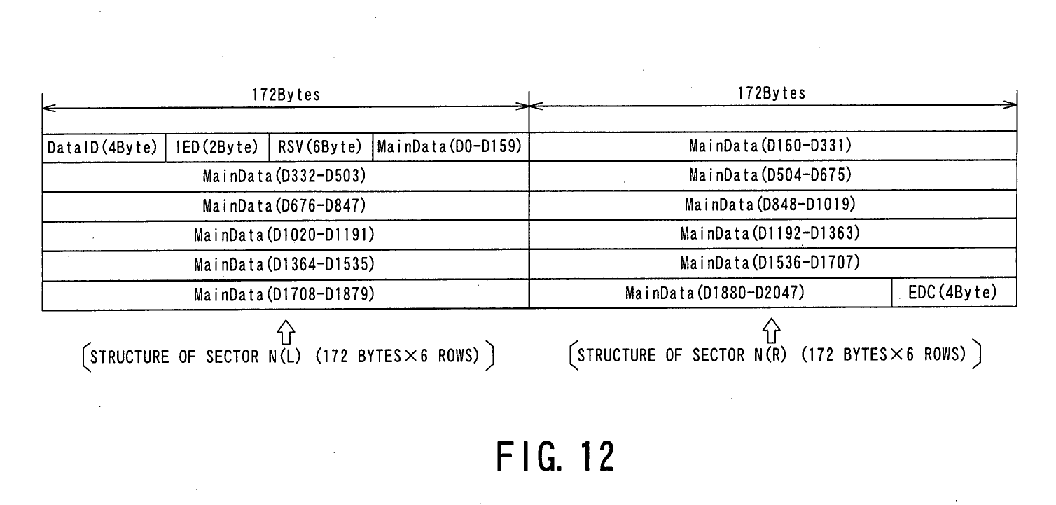

FIG. 12 illustrates the data structure of the sector. The sector contains the following fields from the head to the tail thereof: a 4-byte “Data ID” (identifier for each sector); a 2-byte “EID (ID error detection)”; a 6-byte reserved area (“RSV”); a 2048-byte (2-Kbyte) field for storing main data starting from D0 to D2047; and a 4-byte EDC (error detection code).

The EDC is used for detecting an error in the 2060-byte data starting from the head to the tail of the main data (up to D2047). However, the EDC does not provide the error correction capability. Even when the error correction is impossible on an ECC block basis (as will be described below), it can be determined whether the data is effective or not (i.e., an error can be detected or not) on a sector basis by using the EDC.

Since the main data area is scrambled, an error must be detected using the EDC after the main data is descrambled.

As shown in FIG. 12, the sector is divided into 12 rows: 6 rows in the left and 6 rows in the right. One row is 172 bytes. The 10-byte PI code is attached to the 172-byte row to form the PI row.

FIG. 12 illustrates the structure of the sector of the HD DVD-RW. The basic structure of the sector of the HD DVD-RW is similar to that of the known DVD. However, the only difference is as follows: in the HD DVD-RW, the sector is divided into 6 rows, each including left and right sub-sectors, while, in the known DVD, as shown in FIGS. 9 and 10, the rows are not divided into left and right sub-sectors and the 12 rows are arranged in a line.

(2) Configuration of Information Recording/Playback Apparatus and Basic Recording/Playback Operation

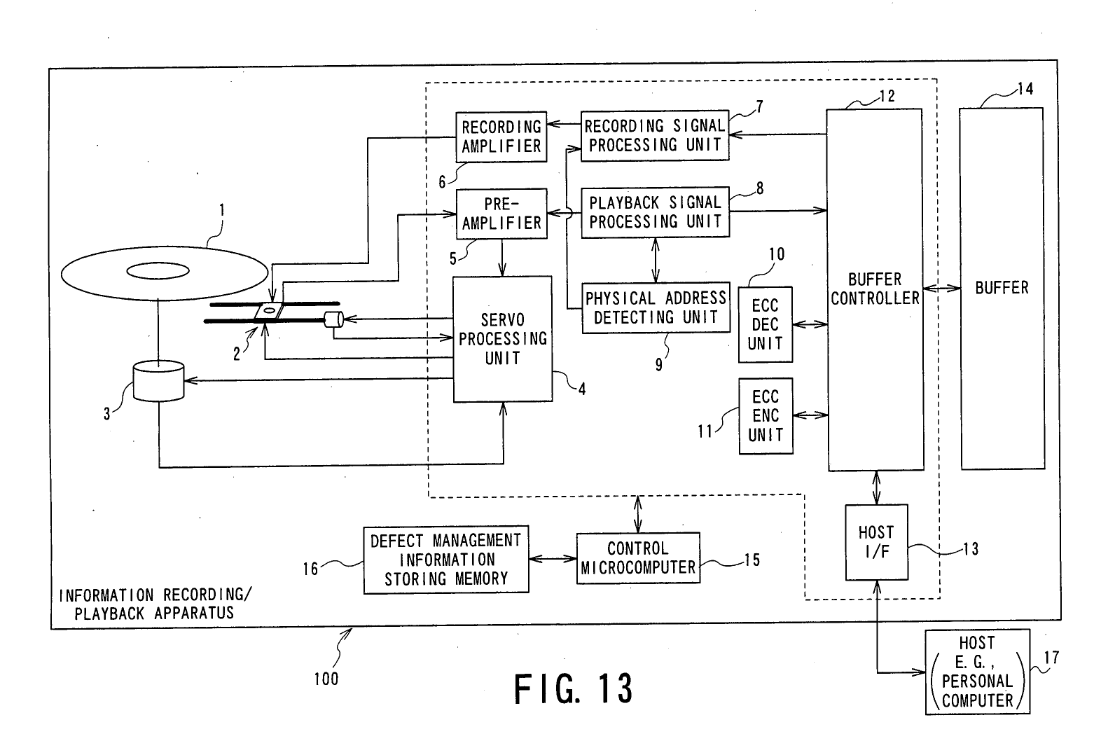

FIG. 13 illustrates an exemplary system configuration of the information recording/playback apparatus 100 according to the present embodiment.

The information recording/playback apparatus 100 includes an optical pickup 2 for writing information to or reading information from the information storage medium 1, a spindle motor 3 for rotating the information storage medium 1, a servo processing unit 4 for performing focus control and tracking control of the optical pickup 2 and controlling the rotation of the spindle motor 3, a pre-amplifier 5 for controlling the gain of a playback signal output from the optical pickup 2, a playback signal processing unit 8 for processing the playback signal, a physical address detecting unit 9 for detecting a physical address on the information storage medium 1 from the playback signal, a recording signal processing unit 7 for processing a recording signal onto the information storage medium 1, a recording amplifier 6 for amplifying the recording signal and outputting the amplified signal to the optical pickup 2, an ECC ENC unit 11 for encoding data to be recorded on the information storage medium 1 while adding an ECC code, an ECC DEC unit 10 for decoding and error-correcting data read from the information storage medium 1 using an ECC code, a buffer 14 for temporarily storing recording data and playback data, a buffer controller 12 for controlling the input and output of the buffer 14, a HOST I/F 13 serving as an interface between the information recording/playback apparatus 100 and, for example, a personal computer 17, a control microcomputer 15 for performing overall control of the information recording/playback apparatus 100, and a defect management information storing memory 16 for storing defect management information.

The basic recording and playback operation of the information recording/playback apparatus 100 having such a structure is described below. The basic playback operation is described first.

Upon receiving a playback instruction from, for example, the personal computer 17, the information recording/playback apparatus 100 moves the optical pickup 2 to the position of a DMA on the information storage medium 1 and reads defect management information recorded in the DMA. As described above, the DMA is recorded on an ECC block basis, and the defect management information is read out on an ECC block basis. The readout defect management information is temporarily stored in the buffer 14. The ECC DEC unit 10 performs error correction on the stored defect management information on an ECC block basis using a PI code and a PO code. If no error is found on the stored defect management information or if an error can be corrected even when the error is found, the defect management information is stored in the defect management information storing memory 16.

Here, if the error of the defect management information read out of the DMA cannot be corrected on an ECC block basis, the process flow proceeds to a DMA compensation process, which will be described below.

Thereafter, the information recording/playback apparatus 100 sequentially moves the optical pickup 2 to a position at a physical address of data to be played back so as to play back the user data from the user area of the information storage medium 1. At that time, the information recording/playback apparatus 100 references the defect management information stored in the defect management information storing memory 16. If the user data to be played back has been relocated from the user area to the spare area, the information recording/playback apparatus 100 reads out the corresponding user data from the physical address of the spare area on the basis of the defect management information.

The user data is also encoded using an error correction code. Like the defect management information, the user data is error-corrected by the ECC DEC unit 10. Thereafter, the information recording/playback apparatus 100 externally outputs a playback signal to, for example, the personal computer 17 via the HOST I/F 13.

The basic recording operation is described next. Upon receiving a recording instruction and recording data from, for example, the personal computer 17, the information recording/playback apparatus 100 temporarily stores the recording data in the buffer 14. The ECC ENC unit 11 then carries out an encoding operation, such as an addition of a PI code and a PO code on an ECC block basis. Thereafter, the information recording/playback apparatus 100 converts a logical address received from the personal computer 17 to a physical address on the information storage medium 1. The information recording/playback apparatus 100 moves the optical pickup 2 to that physical address so as to record the recording data on the information storage medium 1.

At that time, the information recording/playback apparatus 100 references the defect management information stored in the defect management information storing memory 16. If the address to be recorded is a defective address (an address to be relocated), the information recording/playback apparatus 100 records the recording data at the replacement address in the spare area.

Subsequently, the information recording/playback apparatus 100 verifies the recorded data (performs recording verification). The verification is basically carried out in the procedure similar to that of the data playback. If no error is found in the data played back for verification or if an error can be corrected using the error correction code, the data is successfully recorded. In contrast, if the error cannot be corrected using the error correction code, the information recording/playback apparatus 100 determines that a defect has occurred in the recording area on the information storage medium 1 and records the data in the spare area serving as the replacement area. In addition, the address of the relocated data and the replacement address are newly recorded in the DMA.

The above-described basic operation assumes that the defect management information recorded in the DMA has been correctly read out (i.e., an error can be corrected). The same DMA is recorded at 4 physically separated locations (in the DMAs 1 to 4) and, therefore, the reliability is ensured. Additionally, in the HD DVD-RW, up to 100 DMAs are replaceably provided so that the quality degradation of the DMA itself can be recovered.

However, if an error of the defect management information read out from the DMA cannot be corrected despite the above-described techniques, the user data cannot be read out using the defect management information. This has a serious impact.

Accordingly, even when the readout defect management information cannot be error-corrected on an ECC block basis, means and a method for acquiring available defect management information by compensating for the defect management information are described next.

(3) Compensating Operation of Defect Management Information

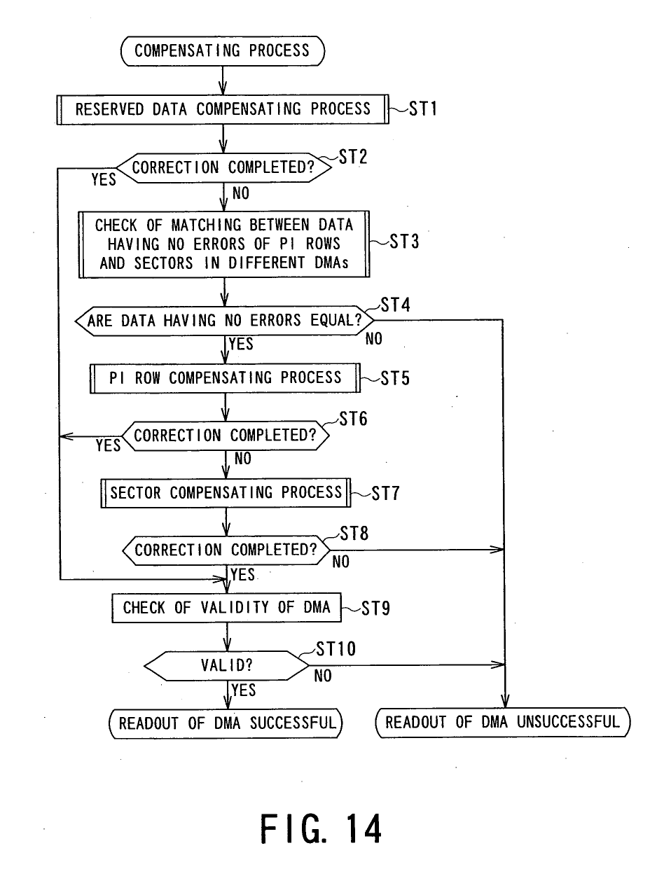

FIG. 14 is a flow chart of a compensating operation on defect management information. The details of this operation are described below. FIG. 14 illustrates the outline of the overall operation.

At step ST1, the compensating operation is carried out using reserved data contained in the defect management information (DDS/PDL and SDL). If an error can be corrected after the compensating operation is completed, the process proceeds to step ST9. At step ST9, the compensated DMA is verified. If the DMA is valid, it is determined that the readout of the DMA is successful.

As shown in FIGS. 7 and 8, the reserved areas of the PDL and SDL are all filled with “1”, namely, “ff (hexadecimal).” Accordingly, if data of a row having all “1”s is found, the following data must be all “1”s in the reserved area.

If the reserved area is detected and bits of “1” are forcibly written to the entire area, the error occurring in the reserved area can be corrected. Thus, the number of errors occurring in the ECC block can be reduced. As a result, errors that were uncorrectable in an ECC block due to the presence of too many errors could be corrected (“Yes” at step ST2).

If the error is uncorrectable even after the operation at step ST1 is carried out, data having no errors are compared among the DMAs. Even when the error is uncorrectable on an ECC block basis, not all the errors in all the PI rows in an ECC block are uncorrectable. A PI row without an error or a PI row that is correctable using the PI code may be present (hereinafter such a PI row is referred to as an “alive” PI row). This alive PI row can be detected and can be then compensated for. The compensating operation is carried out at the subsequent step ST5. At step ST3, data matching between this PI row and the corresponding PI row in another DMA is checked in order to determine the reliability of the alive PI row. If only one alive PI row is found in the four DMAs or if two or more alive PI rows are found, but the data of the PI rows do not match, the reliability of the data in the alive PI row is considered to be low. Thus, the compensating operation for the data is terminated (“No” at step ST4).

Similarly, even when the error is uncorrectable on an ECC block basis, not all the errors in all the sectors in an ECC block are necessarily detected. A sector without an error or a sector that is correctable using the PI code may be present (such a sector is referred to as an “alive” sector). This alive sector can be detected and can be then compensated for. The compensating operation is carried out at the subsequent step ST7. At step ST3, data matching between this sector and the corresponding sector in another DMA is checked in order to determine the reliability of the alive sector. If only one alive sector is found in the 4 DMAs or if two or more alive sectors are found, but the data of the sectors do not match, the reliability of the data in the alive sector is considered to be low. Thus, the compensating operation for the data is terminated (“No” at step ST4).

At step ST5, the data in an alive PI row is extracted. The extracted data is copied to a “dead” PI row in another DMA. This operation is repeated for all the four DMAs so that an alive PI row can compensate for a dead PI row. Thus, the number of errors in each DMA reduces. As a result, errors that were unable to be corrected in an ECC block due to too many errors could be corrected (“Yes” at step ST6).

Similarly, at step ST7, the data in an alive sector is extracted. The extracted data is copied to a “dead” sector in another DMA. This operation is repeated for all the four DMAs so that an alive sector can compensate for a dead sector. Thus, the number of errors in each DMA reduces. As a result, errors that were unable to be corrected in an ECC block due to too many errors could be corrected (“Yes” at step ST8).

At step ST9, the validity of the compensated data is checked. The validity check is carried out by comparing, for example, an “expected value” with the compensated data. The expected values are values shown in the “expected value” entries of the byte allocation table in FIGS. 5 to 8. These expected values do not depend on the user data to be recorded. The expected values are constant values that do not vary during recording and playback. Thus, by comparing the expected value with the compensated data, the reliability of the compensated data can be determined.

In FIG. 14, the compensating operations (i.e., the compensating operation using the reserved data, the compensating operation using the PI row, and the compensating operation using the sector) are sequentially carried out. However, these operations may be independently carried out. Alternatively, any two or more of the compensating operations may be combined and carried out. Furthermore, the data comparing operation between the DMAs (step ST3) or the verifying operation (step ST9) may be eliminated.

The details of each compensating operation are described next.

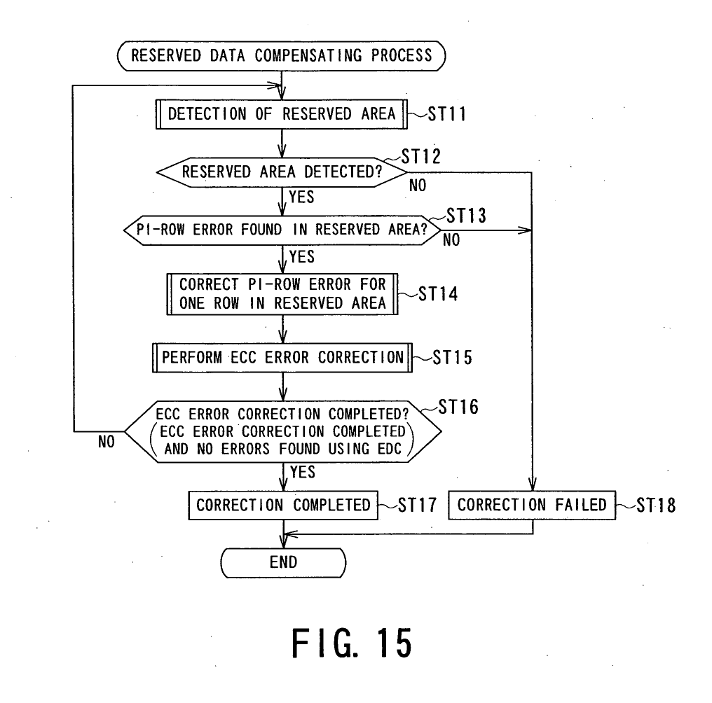

FIG. 15 is a flow chart of the detailed reserved data compensating operation. At step ST11, the reserved area contained in the PDL or the SDL is detected.

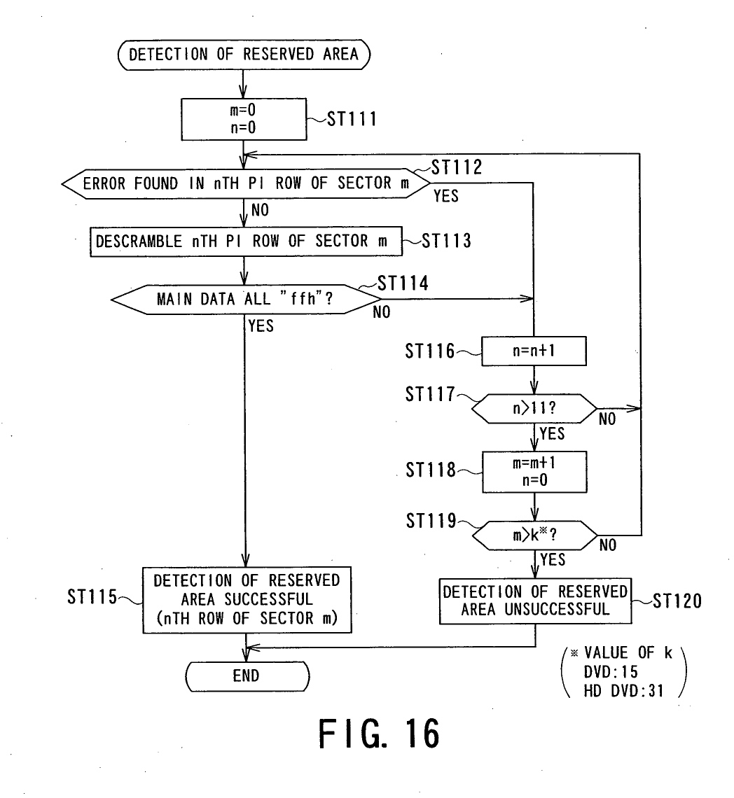

FIG. 16 is a flow chart of an operation for detecting the reserved area. One ECC block includes 16 sectors (for known DVDs) or 32 sectors (for HD DVD-RWs). One sector includes 12 PI rows. Accordingly, after the initialization process is carried out at step ST111 (a sector number m=0 and a PI-row number n=0), a reserved area is searched for from the head of the ECC block (where m=0 and n=0) while sequentially updating the sector number m and the PI-row number n.

More specifically, a PI row that has been error-corrected using the PI code (i.e., that has no error) is searched for (“Yes” at step ST112). The main data in that PI row is descrambled (step ST113). If the descrambled main data is all “1”s (“ff”s in hexadecimal) (“Yes” at step ST114), it is determined that the reserved area is successfully detected.

However, if the error of the PI row cannot be corrected or if the main data is not all “1”s (“ff”s in hexadecimal), a reserved area is searched for throughout the ECC block while sequentially updating the sector number m and the PI-row number n (steps ST116 to ST119). If a PI row having all “1”s cannot be found, it is determined that the detection of the reserved area is unsuccessful.

If a reserved area is found (“Yes” at step ST12 in FIG. 15), a PI row that is uncorrectable (i.e., that has an error) is searched for (“Yes” at step ST13). Thereafter, the PI row is all filled with “1”s (i.e., is compensated for using “1”s) (step ST14).

Consequently, the PI row having an error is correctly compensated for. The number of errors in the ECC block is reduced. Then, in this stage, the error correcting operation is attempted for the ECC block (step ST15). If the error correction is possible on an ECC block basis, the compensating operation is successful. By determining that no errors have been detected using the EDC provided for each sector, the reliability can be further increased.

If the error cannot be corrected on an ECC block basis, the process returns to the first step of FIG. 15 and the operations are repeated again. The PI rows in the reserved area are filled with “1”s row by row. If the error cannot be corrected even after this operation is carried out throughout the ECC block, it is determined that the error correction using the reserved area compensation has been unsuccessful.

In the process flow in FIG. 15, the PI rows are compensated for row by row. However, after the reserved area can is detected, all the PI rows in the reserved area may be compensated with “1”s at a time.

The details of the comparing operation between PI rows or sectors in the different DMAs (step ST3 in FIG. 14) are described next.

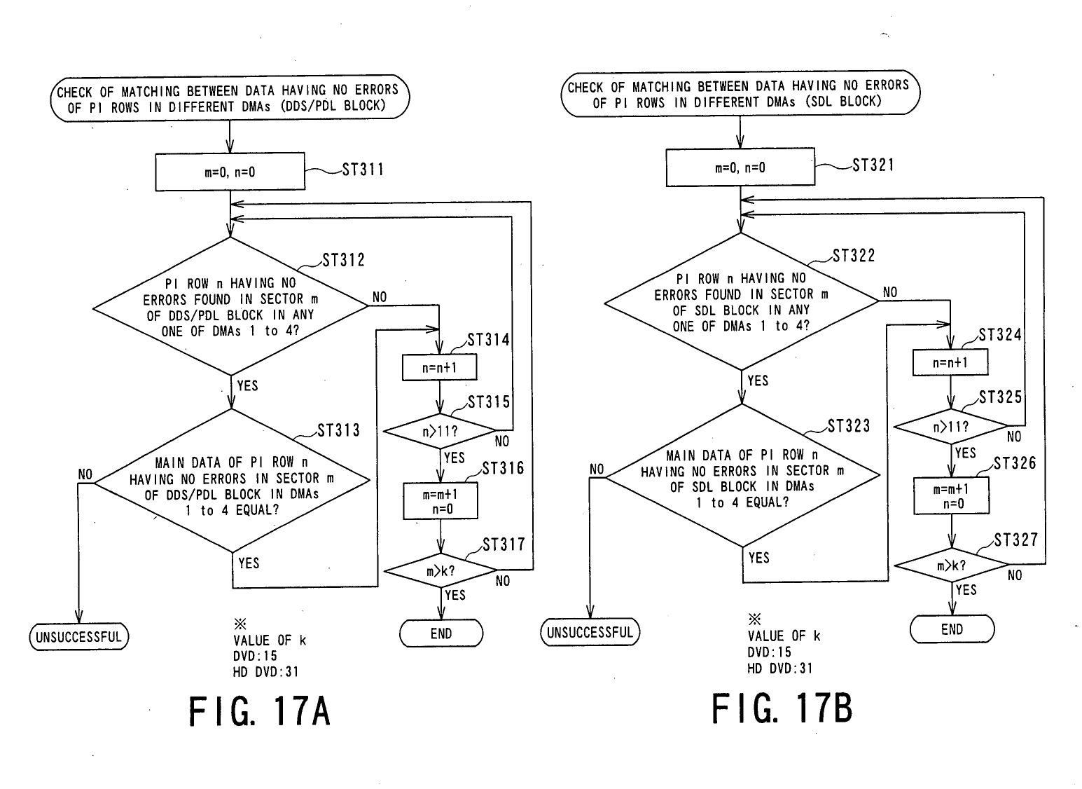

FIGS. 17A and 17B illustrate flow charts of the comparing operation between PI rows in the different DMAs. FIG. 17A illustrates the operation for the DDS/PDL block in the DMA while FIG. 17B illustrates the operation for the SDL block in the DMA. Since both operations are similar, only a description for the operation shown in FIG. 17A is provided here.

At step ST311, the sector number m and the PI-row number n are initialized.

At step ST312, it is determined whether an error has been found in data of a PI row 0 of a sector number 0 of a DMA 1 (and whether the error is correctable using a PI code).

If no error is found in the data of the PI row 0 of the sector number 0, the presence of an error in data of the corresponding rows in the DMAs 2 to 4 is checked. If no error is found in the corresponding rows, the main data is descrambled and it is determined whether the data in the corresponding PI rows are equal (step ST313).

This operation is carried out for all the PI rows in all the sectors. If a PI row having no errors is present and the data of the PI row is equal to data of the corresponding PI row of at least one other DMA, it is determined that the matching check between the PI rows in the different DMAs has been successful.

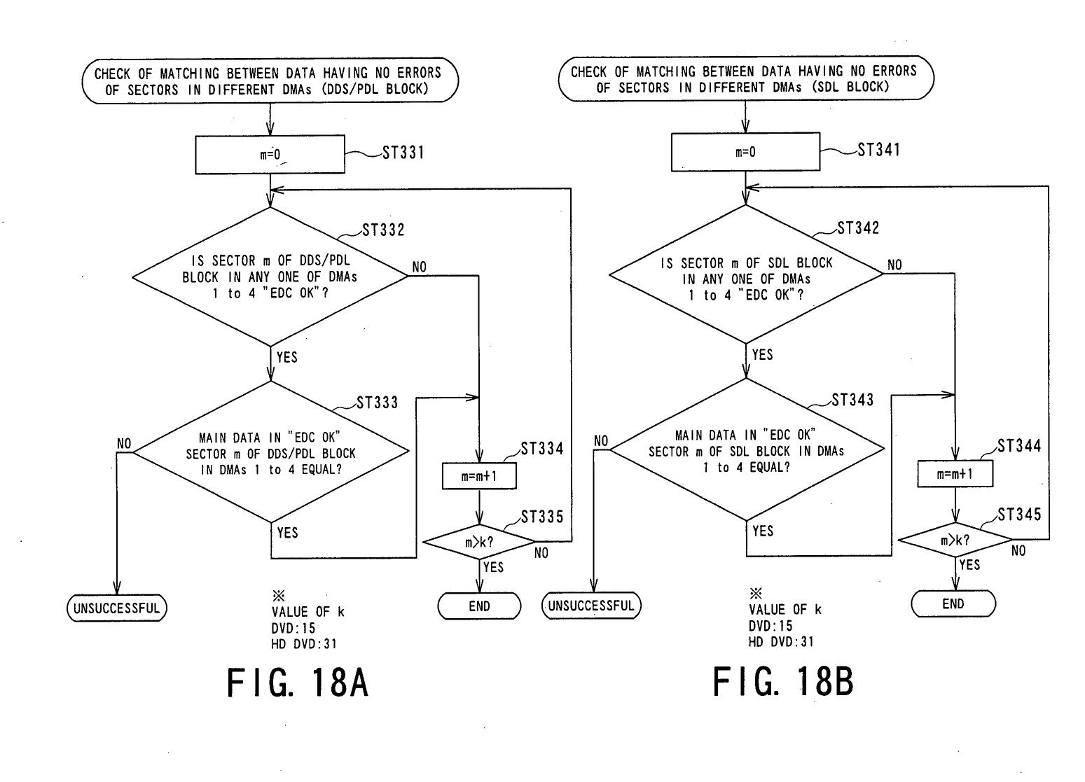

FIGS. 18A and 18B illustrate flow charts of the comparing operation between sectors in the different DMAs. FIG. 18A illustrates the operation for the DDS/PDL block in the DMA while FIG. 18B illustrates the operation for the SDL block in the DMA. Since both operations are similar, only a description for the operation shown in FIG. 18A is provided here.

At step ST331, the sector number m is initialized.

At step ST332, it is determined whether an error has been found in data of a sector number 0 of the DMA 1. To detect an error, the main data is descrambled and the EDC provided to each sector is then used.

If no errors are found in the data of the sector having a sector number 0, the presence of an error in data of the corresponding rows in the DMAs 2 to 4 is checked. If no errors are found in the corresponding rows, it is determined whether the data in the corresponding sectors are equal (step ST333).

This operation is carried out for all the sectors. If a sector having no error is present and the data of the sector is equal to data of the corresponding sector of at least one other DMA, it is determined that the matching check between the sectors in the different DMAs is successful.

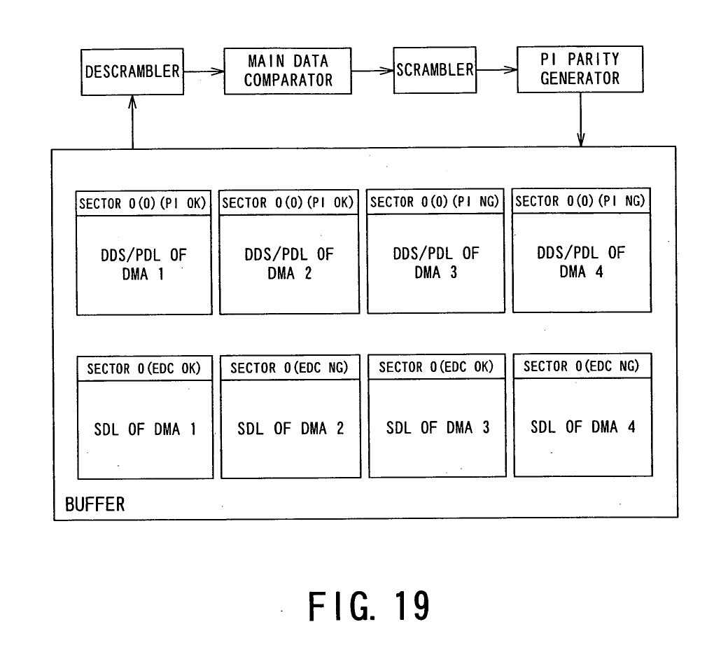

As shown in FIG. 19, these determinations can be made by comparing data after storing the data in the buffer 14 (see FIG. 13) from the DMAs 1 to 4. In an example shown in FIG. 19, the data of the sector number 0 and PI row number 0 of the DDS/PDL block have no errors in the DMA 1 and DMA 2 (“PI OK”). However, the data have errors in the DMA 3 and DMA 4 (“PI NG”). In this case, the PI rows in the DMA 1 and DMA 2, which have no errors, are descrambled and then the main data are compared with each other to determine whether the data match (comparison operation between PI rows in the different DMAs).

In addition, the data of the sector number 0 in the SDL block have no errors in the DMA 1 and DMA 3 (“EDC OK”). However, the data have errors in the DMA 2 and DMA 4 (“EDC NG”). In this case, the data of the sector number 0 in the DMA 1 and DMA 3, which have no errors, are descrambled and then the main data are compared with each other to determine whether the data match (comparison operation between sectors in the different DMAs).

The operation of compensating for the PI row is described next in detail.

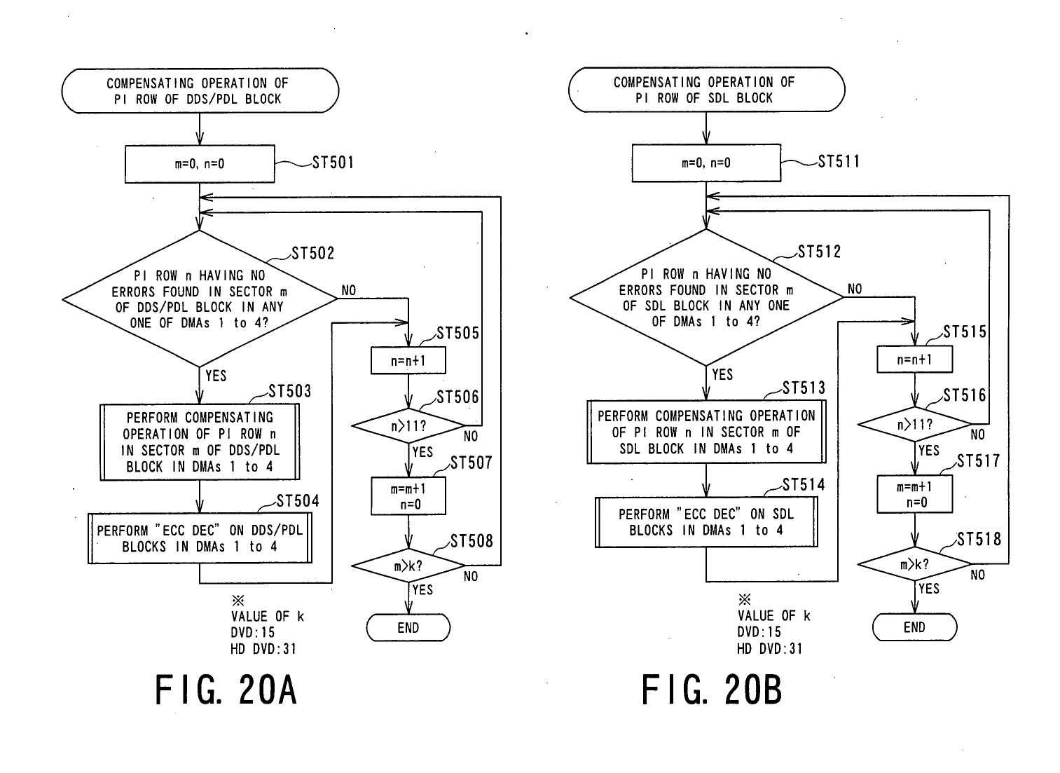

FIG. 20A and 20B illustrate flow charts of the PI row compensating operation. FIG. 20A illustrates the operation for the DDS/PDL block in the DMA while FIG. 20B illustrates the operation for the SDL block in the DMA. Since both operations are similar, only a description for the operation shown in FIG. 20A is provided here.

At step ST501, the sector number m and the PI-row number n are initialized.

At step ST502, it is determined whether an error has been found in data of a PI row 0 of a sector number 0 of the DMA 1 (and the error is correctable using a PI code). This determination has been already made at step ST312 (see FIG. 17). The result of that determination may be applied.

If no errors have been found in the data of the PI row 0 of the sector number 0, the data in the PI row (an alive PI row) is copied to the corresponding PI row determined to have an error (i.e., a dead PI row) in the DMAs 2 to 4 (step ST503).

At this stage, the “dead PI row” lives again. Thus, the number of errors in the DDS/PDL block, which was determined to have errors, is reduced. Subsequently, the error correction operation on an ECC block basis is attempted (step ST504).

This operation is carried out for all the PI rows in all the sectors. Consequently, the data of the PI row having no errors in the DMA 1 has been copied to the PI row having an error in another DMA.

The similar operation is carried out for the DMA 2. As a result, the data of the PI row having no errors in the DMA 2 has been copied to the PI row having an error in another DMA.

The similar operation is carried out for the DMAs 3 and 4. By carrying out this operation, the data of the “alive PI row” is used for compensating for the DMAs to reduce the number of errors of each DMA.

Consequently, the ECC block that was uncorrectable on an ECC block basis due to the presence of too many errors could be corrected.

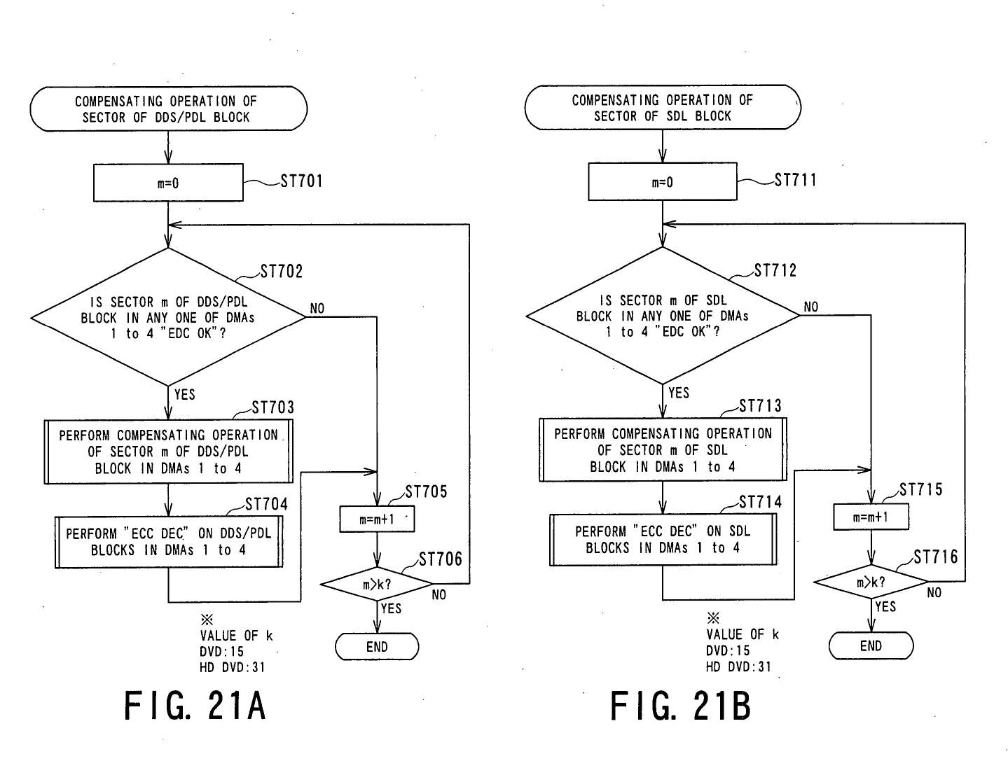

FIG. 21A and 21B illustrate flow charts of the sector compensating operation. FIG. 21A illustrates the operation for the DDS/PDL block in the DMA while FIG. 21B illustrates the operation for the SDL block in the DMA. Since both operations are similar, only a description for the operation shown in FIG. 21A is provided here.

At step ST701, the sector number m is initialized.

At step ST702, it is determined whether errors have been found in data of a sector number 0 of the DMA 1. To detect an error, the main data is descrambled and the EDC provided to each sector is then used. This determination has been already made at step ST332 (see FIG. 18). The result of that determination may be applied.

If no errors have been found in the data of the sector having a sector number 0, the data in the sector (an alive sector) is copied to the corresponding sector determined to have an error (i.e., a dead sector) in the DMAs 2 to 4 (step ST703).

At this stage, the “dead sector” lives again. Thus, the number of errors in the DDS/PDL block, which was determined to have errors, is reduced. Subsequently, the error correction operation on an ECC block basis is attempted (step ST704).

This operation is carried out for all the sectors. Consequently, the data of the sector having no errors in the DMA 1 has been copied to the sector having an error in another DMA.

The similar operation is carried out for the DMA 2. As a result, the data of the sector having no errors in the DMA 2 has been copied to the sector having an error in another DMA.

The similar operation is carried out for the DMAs 3 and 4. By carrying out this operation, the data of the “alive sector” is used for compensating for the DMAs to reduce the number of errors of each DMA.

Consequently, the ECC block that was uncorrectable on an ECC block basis due to the presence of too many errors could be corrected.

The above-described compensating operation can be applied to both DDS/PDL block and SDL block.

A compensating operation that is applicable to only the DDS/PDL block is described next. Hereinafter, this operation is referred to as a “DDS/PDL block compensating operation”.

Defect management information recorded in the DDS/PDL block is information relating to initial defects found at the factory and in a formatting operation intentionally carried out by a user. Therefore, the number of updates of the defect management information in the DDS/PDL block is small. As a result, even when a DMA associated with the DDS/PDL block is relocated, the old DMA before the replacement probably contain available defect management information.

Therefore, an area for recording information as to whether the old DMA before the replacement is available or not (hereinafter referred to as “PDL update history information”) is separately provided. In the DDS/PDL block compensating operation, if the error of the DDS/PDL block is found to be uncorrectable, the PDL update history information is referenced. When the old DMA before the replacement is available, that information is used as the defect management information of the current DDS/PDL block. It is noted that the replacement of the DDS/PDL block is not employed by the known DVDs, and therefore, this compensating operation is applicable to the next-generation DVDs (HD DVD-RW).

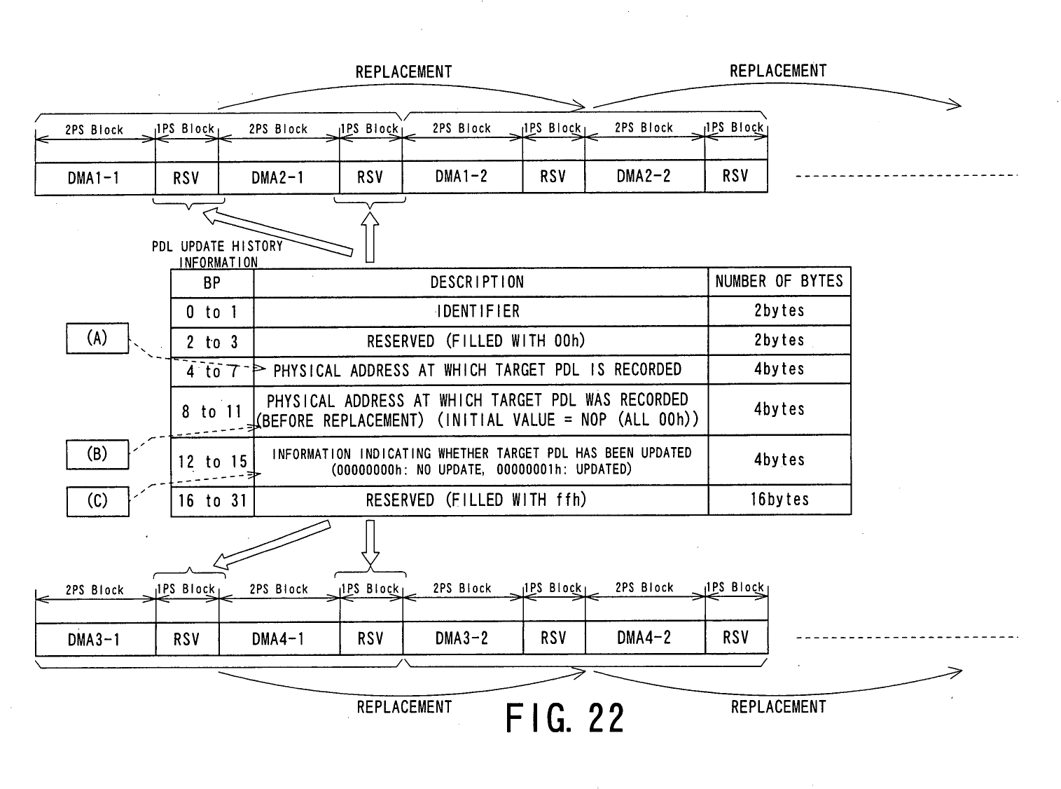

FIG. 22 illustrates an example of the details of the PDL update history information and the recording location of the PDL update history information. The PDL update history information is, for example, 32-byte information, as shown in FIG. 22. A “physical address at which a target PDL (the current PDL) is recorded” is recorded at a position “A”. A “physical address at which the target PDL was recorded before the replacement” is recorded at a position “B”. “Information (a flag) as to whether the target PDL has been relocated or not” is recorded at a position “C”.

This 32-byte PDL update history information is recorded in, for example, a “RSV” area immediately after the DMA. Since the data size of the “RSV” area is 64 Kbytes, 2048 items of the PDL update history information can be recorded in one “RSV” area.

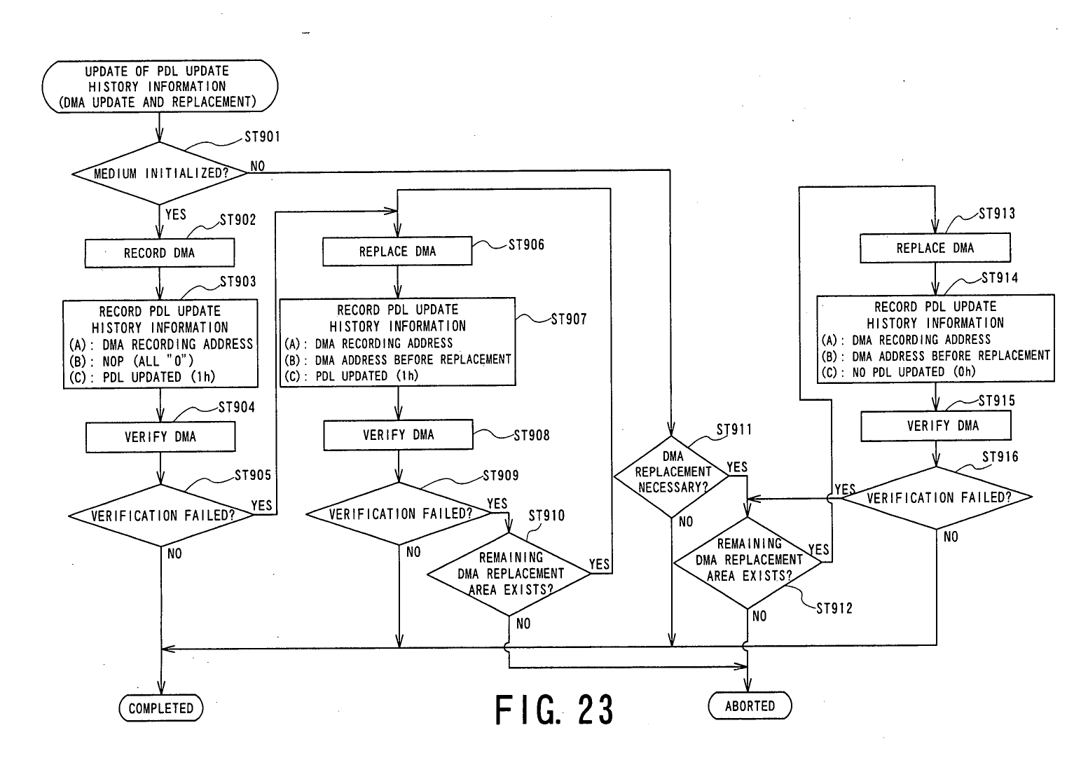

FIG. 23 is a flow chart of the procedure for generating the PDL update history information.

The PDL is updated when the medium is initialized (formatted). Accordingly, at step ST901, it is determined whether the medium has been initialized or not. When the medium is formatted (“Yes” at step ST901), the defect management information is recorded in the DMA (PDL) (step ST902). Simultaneously, the PDL update history information is recorded in the “RSV” area. At that time, the PDL update history information includes the physical address of the DMA (PDL) recorded at the initialization time, the physical address of the DMA (PDL) before the replacement (all “0”s in this case), and a flag indicating that the PDL has been updated (step ST903).

After data is recorded in the DMA (PDL), verification of the data is carried out (step ST904). If the verification fails (“Yes” at step ST905), the DMA is relocated (step ST906). At the same time, the PDL update history information is updated (step ST907). Verification is carried out again (step ST909). The verification is repeated until the verification succeeds as long as the remaining DMA is present.

In contrast, even when the medium is not formatted (“No” at step ST901), the SDL is updated every time a secondary defect occurs during the use of the information storage medium 1. Thus, the replacement of the DMA occurs (“Yes” at step ST911 and step ST913). At the same time, the PDL update history information is updated. However, at that time, since the medium is not formatted, the PDL update flag indicates “no PDL update”.

As described above, the PDL update history information is generated and updated. By using such PDL update history information, even when the defect management information recorded in the current PDL cannot be read out, the defect management information in the old PDL could be used.

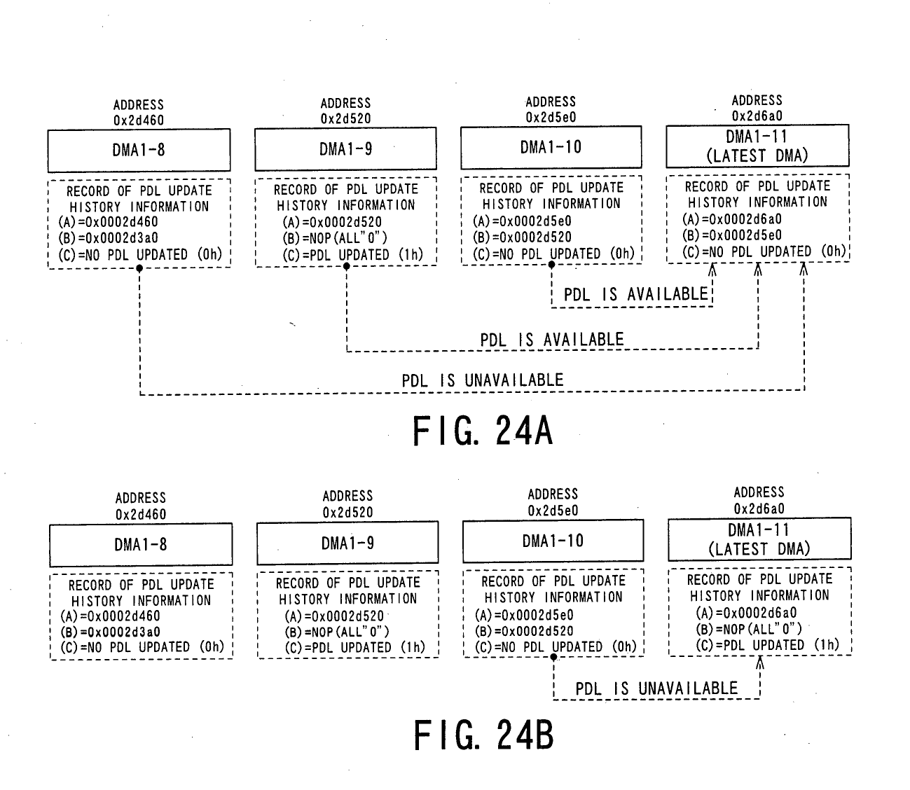

FIG. 24A illustrates the case where the defect management information recorded in the current PDL can be used. In this example, the DMAs 1-8 to 1-11 are relocated. As the DMAs are relocated, the PDL update history information is updated. The updated PDL update history information is also relocated together with the DMA.

When looking at the flags (C) in the updated PDL update history information, each indicating “PDL updated” or “PDL not updated”, it can be seen that the PDL is updated when the DMA 1-8 is relocated to the DMA 1-9. Also, it can be seen that the PDL is not updated when the DMA 1-9 is relocated to the DMA 1-10 and when the DMA 1-10 is relocated to the DMA 1-11. Accordingly, even when the PDL cannot be read out from the latest DMA (DMA 1-11), the PDL recorded in the DMA 1-9 or DMA 1-10 is effective. The compensation can be carried out using this effective PDL.

In contrast, FIG. 24B illustrates the case where the defect management information recorded in the old PDL cannot be used. In this example, it can be seen that the PDL is updated in the DMA 1-11. That is, the PDL has been updated when the DMA 1-10 is relocated to the DMA 1-11, and therefore, the PDL information in the old DMA 1-10 cannot be used. At that time, if the updated PDL (the latest PDL) is unreadable, this compensation operation cannot be applied.

As described above, according to the information storage medium 1, the information recording/playback apparatus 100, and the method for recording and playing back information of the present embodiment, even when the number of errors on an ECC block basis beyond the error correction capability occurs, the defect management information stored in the DMA can be read out. Thus, the loss of the user data can be prevented.

While the invention will be described in conjunction with the preferred embodiments, it will be understood that they are not intended to limit the invention to these embodiments. On the contrary, the invention is intended to be realized by modifying its components within the spirit and scope of the invention as defined by the claims. Additionally, the invention is intended to be realized by combining appropriate components from among a plurality of components disclosed in the preferred embodiments. For example, some of the components may be removed from all the components disclosed in the preferred embodiments. Furthermore, components in a plurality of the preferred embodiments may be appropriately combined.

What is claimed is:

1. A rewritable information storage medium comprising:
a user area for storing user data;
a spare area serving as a replacement area for storing user data that was unable to be stored in the defective area; and
a plurality of defect management areas, each storing the same defect management information, the defect management information being used for playing back the user data relocated and stored in the replacement area, the defect management information being encoded on a predetermined data unit basis using a predetermined error correction code;
wherein, even when all errors of the plurality of defect management areas are uncorrectable on the predetermined data unit basis, in the case where the error of the defect management information stored in any one of the defect management areas is correctable or the error is not found on a data unit basis smaller than the predetermined data unit, the defect management information is compensated for on the basis of the smaller data unit.

2. The information storage medium according to claim 1, wherein the predetermined data unit comprises an effective data area for storing the defect management information and a reserved data area existing from the end of the effective data area to the end of the predetermined data unit and the reserved data is filled with a predetermined bit pattern, and wherein the predetermined data unit is searched from the head thereof and, when the reserved data area is detected, the reserved data area is forcibly written with the bit pattern so that the error correction capability of the predetermined data unit for the effective data area is further increased.

3. The information storage medium according to claim 1, wherein the predetermined data unit comprises a plurality of sectors, each being error-detectable, and the same data is stored in the plurality of the defect management areas on a sector-by-sector basis, and wherein, when an error is not detected in data of at least two sectors among the corresponding sectors in the plurality of the defect management areas and the data of the at least two sectors are equal, data in the corresponding sector having an error is replaced with the equal data.

4. The information storage medium according to claim 2, wherein the predetermined data unit comprises a plurality of sectors, each being error-detectable, and the same data is stored in the plurality of the defect management areas on a sector-by-sector basis, and wherein, when an error is not detected in data of at least two sectors among the corresponding sectors in the plurality of the defect management areas and the data of the at least two sectors are equal, data in the corresponding sector having an error is replaced with the equal data.

5. The information storage medium according to claim 1, wherein the predetermined data unit comprises a plurality of rows, each being error-correctable, and the same data is stored in the plurality of the defect management areas on a row-by-row basis, and wherein, when an error is correctable in data of at least two rows among the corresponding rows in the plurality of the defect management areas and the data of the at least two rows are equal, data in the corresponding row having an uncorrectable error is replaced with the equal data.

6. The information storage medium according to claim 2, wherein the predetermined data unit comprises a plurality of rows, each being error-correctable, and the same data is stored in the plurality of the defect management areas on a row-by-row basis, and wherein, when an error is correctable in data of at least two rows among the corresponding rows in the plurality of the defect management areas and the data of the at least two rows are equal, data in the corresponding row having an uncorrectable error is replaced with the equal data.

7. The information storage medium according to claim 1, wherein the compensated defect management information is compared with a predetermined reference value and wherein, if the compensated defect management information is equal to the predetermined reference value, the relocated and stored user data is played back using the compensated defect management information.

8. The information storage medium according to claim 1, wherein the compensated defect management information is compared with a predetermined reference value and wherein, if the compensated defect management information is equal to the predetermined reference value, the error-uncorrectable defect management information is replaced with the compensated defect management information.

9. The information storage medium according to claim 1, further comprising:
a plurality of defect management areas used for updating the defect management information; and
an initial defect management information update storage area for storing initial defect management information relating to initial defects of the information storage medium, the initial defect management information being part of the defect management information, the initial defect management information including the presence of an update of the initial defect management information, an address of the defect management area before the update, and an address of the defect management area after the update;
wherein, even when all of the plurality of defect management areas are error-uncorrectable on the predetermined data unit basis, the initial defect management information contained in the defect management area before the update is extracted on the basis of information stored in the initial defect management information update storage area, and the initial defect management information contained in the defect management area after the update is replaced with the extracted initial defect management information.

10. An information recording/playback apparatus for recording data on and playing back data from a rewritable information storage medium, comprising:
first storing means for storing user data in a user area;
second storing means for storing user data that was unable to be stored in a defective area of the user area in a spare area serving as a replacement area;
third storing means for encoding defect management information on a predetermined data unit basis using a predetermined error correction code and storing the same defect management information in a plurality of defect management areas, the defect management information being used for playing back the user data relocated and stored in the replacement area; and
compensating means for compensating for the defect management information on a data unit basis smaller than the predetermined data unit in the case where the error of the defect management information stored in any one of the defect management areas is correctable or the error is not found on the basis of the smaller data unit even when all errors of the plurality of defect management areas are uncorrectable on the predetermined data unit basis.

11. An information recording/playback method for recording data on and playing back data from a rewritable information storage medium, comprising the steps of:
storing user data in a user area;
storing user data that was unable to be stored in a defective area of the user area in a spare area serving as a replacement area;
encoding defect management information on a predetermined data unit basis using a predetermined error correction code and storing the same defect management information in a plurality of defect management areas, the defect management information being used for playing back the user data relocated and stored in the replacement area; and
compensating for the defect management information on a data unit basis smaller than the predetermined data unit in the case where the error of the defect management information stored in any one of the defect management areas is correctable or the error is not found on the basis of the smaller data unit even when all errors of the plurality of defect management areas are uncorrectable on the predetermined data unit basis.
